(19) United States
(12) Patent Application Publication
(10) Pub. No.: US 2015/0339097 A1
(43) Pub. Date: Nov. 26, 2015

(54) VOICE BLASTER

(71) Applicant: Glenn Squires, Bethlehem, PA (US)

(72) Inventor: Glenn Squires, Bethlehem, PA (US)

(21) Appl. No.: 14/715,515

(22) Filed: May 18, 2015

Related U.S. Application Data
(60) Provisional application No. 61/994,695, filed on May 16, 2014.

(51) Int. Cl. G06F 3/16; H05K 5/00

(52) U.S. Cl. CPC G06F 3/165; H05K 5/0017; H05K 5/0086

(57) ABSTRACT

The Voice Blaster is a recordable audio player with a playback mode that is automatically activated utilizing an integrated motion sensor.

### CLAIM OF PRIORITY

This patent application claims priority under 35 USC 119 (e) (1) from U.S. Provisional Patent Application Ser. No. 61/994,695 filed May 16, 2014, of common inventorship herewith entitled, “Voice Blaster,” which is incorporated herein by reference as though the same were set forth in its entirety.

### FIELD OF THE INVENTION

The present invention pertains to the field of audio electronics, and more specifically to the field of recordable audio players.

### BACKGROUND OF THE INVENTION

The prior art has put forth several designs for recordable audio players. Among these are:

US Patent 2012/0244969 to Yehuda Binder describes a device that includes a signaling means and a motion sensor, and logic for activating or controlling the signaling means in response to a sensed motion according to an embedded logic. The device is used as a toy and is shaped as a play ball or a handheld unit. It is powered from a battery, either chargeable from an AC power source directly or contactless by using induction or by converting electrical energy from harvested kinetic energy. The embedded logic activates or controls the signaling means, predictably or randomly, in response to sensed acceleration magnitude or direction, such as sensing the crossing of a preset threshold or sensing the peak value. The visual means is a numeric display for displaying a value associated with the count of the number of times the threshold is exceeded or the peak magnitude of the acceleration sensed.

US Patent 2012/0265535 to Donald Ray Bryant-Rich and Diana Eve Barshaw-Rich describes a personal voice operated reminder system. In one embodiment, the system is worn as a device on the body in a form similar to a watch, bracelet or necklace. In a second embodiment, the system is a device normally held in a person's pocket or purse. In a third embodiment, the system is a method added as an application to already existing devices such as PDAs or cellular telephones. This device is configured to record reminders using speech recognition and to play back the reminder message in accordance with directions received using speech recognition, position or motion inputs.

U.S. Pat. No. 7,218,203 to Gene Williams describes a motion activated, voice controlled reminder system, wherein a programmable device automatically reminds the intended receiver of a future event without any extraordinary action on the part of the recipient. This invention enables a user to use a telephone to leave a message on a recording unit, specifying a date for message delivery wherein the message is stored in a microprocessor until the programmed date. When motion is detected by the motion detector, the microprocessor audibly announces the reminder message.

None of these prior art references describe the present invention.

### SUMMARY OF THE INVENTION

It is an object of the present invention to provide a recordable audio player with a playback mode that is automatically activated utilizing an integrated motion sensor.

### BRIEF DESCRIPTION OF THE DRAWINGS

FIG. 1 is a illustrative prototypical front view of the present invention mounted on a wall.

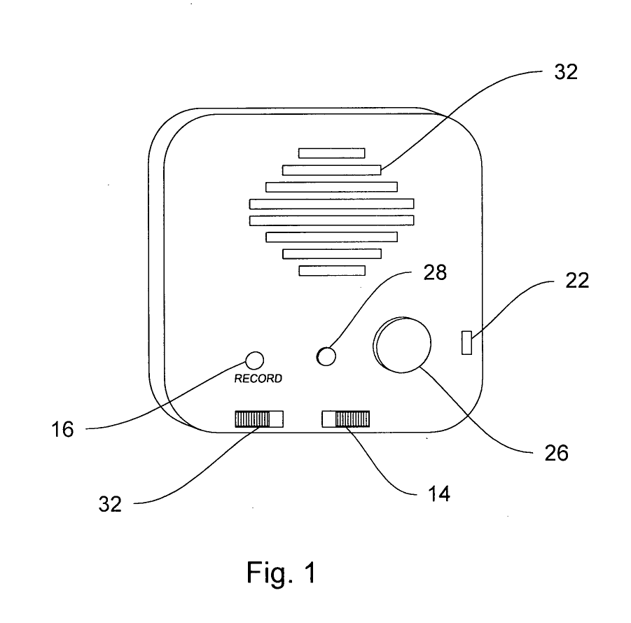

### DETAILED DESCRIPTION OF THE INVENTION

Nothing beats a good laugh. Relieving tension and creating fun diversion from stresses of daily life, laughter is synonymous with joy and good will. Perhaps this is why so many people enjoy telling jokes or playing a good natured prank. Because laughter is so delightful and beneficial, a variety of novelty items are produced simply to invoke good natured humor and laughter. From realistic looking fake dog poop dropped strategically on a freshly cleaned carpet to a seemingly dribble glass offered to a friend at a casual gathering to a whoopee cushion placed on an unsuspecting coworker's chair, these novelty items provide individuals with a harmless and hilarious means of encouraging laughter.

The present invention, hereinafter referred to as the Voice Blaster, is a unique portable recorder and audio player utilized to record funny sentiments or sounds. An integrated motion sensor 14 automatically activates the Voice Blaster's playback mode. A user records various humorous sentiments on the Voice Blaster by pressing the record button 16 and then positions the device out of sight where it is activated inadvertently by an unsuspecting passerby. The Voice Blaster provides a clever means of throwing one's voice, affording a fun and unique means of encouraging laughter and merriment. An alternate use of the Voice Blaster is to function as a security device. A user records messages or alarm sounds to be emitted as effective deterrents when intruders or thieves pass an area where the present invention is hidden.

The motion of an unsuspecting passerby activates the Voice Blaster's selected, message or sound so that the passerby suddenly hears the recorded message or sound without having any idea as to where the sound is originating. Comprising a square shaped casing manufactured of heavy duty plastic or comparable shatterproof material, the compact Voice Blaster measures approximately four inches in length by four inches in width. The present invention is manufactured in a larger size measuring approximately six inches in length by six inches in width. Housed within the Voice Blaster is a simple audio recorder with which the user records funny or deterrent messages, sentiments or sounds. These messages or sounds are emitted through integrated speakers when a passing motion activates the Voice Blaster.

The present invention contains a USB port 22 for connecting to a personal computer and uploading messages and sounds from the computer to the Voice Blaster. Positioned on the front or side of the machine are operational controls including recording, playback, and volume control buttons. Volume control toggle 32 and play button 28 are located on the front of the device. Speaker 32 is also located on the front of the device. The Voice Blaster's integrated motion sensor 22 activates the playback functionality when activity is detected within a specific range of the device. A simple push button activation switch 26 is positioned on the front of the present invention for activating the motion sensor and readying the device for use. The Voice Blaster is powered by replaceable batteries housed within a dedicated battery compartment located on the underside of the present invention.

In an alternate embodiment of the Voice Blaster, the sizes are increased by approximately one inch in length and width, to leave enough interior space for adding side plug outlets for cell phones, iPads and tablets. Adding these capabilities provides listening and charging functions. This alternate embodiment also contains a motion activated camera to record video in approximately thirty second increments. The recorded video automatically is transmitted to an owner's cell phone.

If the owner mounts the Voice Blaster outside their front door, this video capability is activated when someone approaches the front door. Accessing their cell phone, the house owner can view who is at the door and also talk to them by pushing a button on their cell phone. Their cell phone is connected with the Voice Blaster speaker through a wireless network or Bluetooth technology. This viewing capability provides a security system at one's door. If mounted in an internal room, this viewing functionality serves to detect fire. The video camera records a heavy smoke filled room as a fire begins to break out and transmits the video to an owner's cell phone. The Voice Blaster motion sensor also can detect an image of a person falling in a room who is unable to get up and call for help. A thirty second video is uploaded to the owner's cell phone to alert them a family member or guest is lying in the room unable to get up. The aforementioned camera along with the transmittal or uploading capability is turned On and Off from either the Voice Blaster or a connected cell phone.

Application and use of the Voice Blaster is simple and straightforward. A user records or uploads humorous or alarming messages or sounds to be emitted by the Voice Blaster. A teen may record a message, “Raise Billy's allowance!” and hide the present invention behind a coffee maker so the message is activated as his mom or dad makes a pot of coffee in the morning. A host of an informal party with friends may record a hilarious message, “Don't forget to wash your hands!” and hide the device in the guest bathroom. With the specific message or sound recorded on the Voice Blaster, the user hides it in a designated location.

The Voice Blaster sits upright on virtually any flat surface or is mountable on walls or other flat structures. To activate the motion sensor, the user manually pushes the On and Off button switch on the front of the Voice Blaster. Unsuspecting passersby trigger the Voice Blaster as they walk by it and the recorded message is emitted loudly through the present invention's speakers. Initially startled by the message or sound, the unsuspecting victim reacts accordingly. The Voice Blaster remains in place as long as desired, with the user recording new messages or sounds or hiding the Voice Blaster in a new location in to enjoy fresh comic scenarios.

Automatically activated via an integrated motion sensor, the Voice Blaster emits an endless array of messages or sounds that surprise, entertain, confuse or deflect passersby. Hidden on a coworker's desk and programmed with a message firmly instructing the coworker to get to back to work, the Voice Blaster results in instant laughter that lightens a tense environment. Mounted beside a planter and emitting a message to please water the resident plant, the Voice Blaster provides a humorous prank to play on house guests or family members. Although produced primarily for comic purposes, the Voice Blaster functions as an effective security device when a user records a strong warning message or a sound of dogs barking to stop intruders in their tracks and motivate the unscrupulous individuals to flee one's property or vehicle. Durably constructed of quality materials, the Voice Blaster will withstand repeated, good natured use, with ease.

Although this invention has been described with respect to specific embodiments, it is not intended to be limited thereto and various modifications which will become apparent to the person of ordinary skill in the art are intended to fall within the spirit and scope of the invention as described herein taken in conjunction with the accompanying drawings and the appended claims.

1. A recordable audio player comprising: a playback mode that is automatically activated utilizing an integrated motion sensor, a square shaped housing manufactured of heavy duty plastic or comparable shatterproof material, further comprising a USB port for connecting to a personal computer and uploading messages and sounds, further comprising operational controls including recording, playback, and volume control buttons, further comprising a push button activation switch positioned on the front of the player for activating the motion sensor and readying the device for use.

2. The audio player of claim 1, powered by replaceable batteries housed within a dedicated battery compartment located on the underside of the housing.

3. The audio player of claim 1, measuring approximately four inches in length by four inches in width.

4. The audio player of claim 1, measuring approximately six inches in length by six inches in width.
